(19) United States
(12) Patent Application Publication
(10) Pub. No.: US 2025/0208212 A1
(43) Pub. Date: Jun. 26, 2025

(54) ELECTRONIC DEVICE AND OPERATING METHOD THEREOF

(71) Applicant: Industrial Technology Research Institute, Hsinchu (TW)

(72) Inventors: Ching-Iang Li, Hsinchu County (TW); Yung-Sheng Chang, Hsinchu County (TW); Hsuan-Chi Weng, Hsinchu City (TW); Wei Li, Hsinchu City (TW); Siou-Zih Lin, Taichung City (TW); Po-Huan Chou, Hsinchu County (TW); Heng-Chieh Chien, New Taipei City (TW)

(73) Assignee: Industrial Technology Research Institute, Hsinchu (TW)

(21) Appl. No.: 18/966,093

(22) Filed: Dec. 2, 2024

(30) Foreign Application Priority Data
Dec. 21, 2023 (TW) 112150147

(51) Int. Cl. G01R 31/327; H01H 9/54

(52) U.S. Cl. CPC G01R 31/327; H01H 9/54

(57) ABSTRACT

An electronic device and an operating method thereof are provided. The electronic device includes a first switch array, a second switch array, a first signal processor, and a controller. The first signal processor is coupled between the first and second switch arrays. The controller is coupled to the first and second switch arrays. The controller transmits an input signal to the first signal processor through the first switch array, and receives an output signal of the first signal processor through the second switch array. The controller determines whether the output signal is equal to an expected signal to generate a detection result. When the detection result is an abnormal state, the first switch array and the second switch array change the controller to be coupled to a backup signal processor.

### CROSS-REFERENCE TO RELATED APPLICATION

This application claims the priority benefit of Taiwan application serial no. 112150147, filed on Dec. 21, 2023. The entirety of the above-mentioned patent application is hereby incorporated by reference herein and made a part of this specification.

### TECHNICAL FIELD

The disclosure relates to an electronic device, and relates to an electronic device capable of effectively monitoring the reliability of a circuit and an operating method thereof.

### BACKGROUND

In the traditional signal processing architecture, the hardware configurations of signal processing units are usually fixed and cannot be changed. Moreover, when these signal processing units are configured in an open loop design, the front-end controller cannot monitor whether each signal processing unit is operating normally.

In this case, when there is a signal processing unit in an abnormal state in the signal processing architecture, the conventional controller cannot immediately replace or substitute the signal processing unit in the abnormal state, and it is also difficult for the controller to monitor the signal quality of each signal processing unit.

In view of this, how to enable the controller to immediately replace or substitute the abnormal signal processing unit when an abnormality occurs in the signal processing unit to improve the overall reliability of the system is an important issue for persons skilled in the art.

### SUMMARY

The electronic device according to the discourse includes a first switch array, a second switch array, a first signal processor, and a controller. The first signal processor is coupled between the first switch array and the second switch array. The controller is coupled between the first switch array and the second switch array, the controller transmits an input signal to the first signal processor through the first switch array, and receives an output signal of the first signal processor through the second switch array, and the controller determines whether the output signal is equal to an expected signal to generate a detection result. When the detection result is an abnormal state, the first switch array and the second switch array change the controller to be coupled to a backup signal processor.

The operating method of the electronic device according to the discourse includes: providing a first switch array and a second switch array; providing a first signal processor coupled between the first switch array and the second switch array; enabling a controller to transmit an input signal to the first signal processor through the first switch array, and enabling the controller to receive an output signal of the first signal processor through the second switch array; and enabling the controller to determine whether the output signal is equal to an expected signal to generate a detection result, and when the detection result is an abnormal state, changing the controller to be coupled to a backup signal processor by the first switch array and the second switch array.

Several exemplary embodiments accompanied with figures are described in detail below to further describe the disclosure in details.

### BRIEF DESCRIPTION OF THE DRAWINGS

The accompanying drawings are included to provide a further understanding, and are incorporated in and constitute a part of this specification. The drawings illustrate exemplary embodiments and, together with the description, serve to explain the principles of the disclosure.

FIG. 1 is a schematic diagram of an electronic device according to an embodiment of the disclosure.

FIG. 2A and FIG. 2B are operational flow charts illustrating a controller of the electronic device controlling a switch array to be sequentially coupled to a peripheral circuit in a time-division manner according to the embodiment in FIG. 1 of the disclosure.

FIG. 3 is a schematic diagram illustrating the controller of the electronic device detecting whether an abnormal state occurs in a signal processor under test according to an embodiment of the disclosure.

FIG. 4 is an operational flow chart illustrating the controller of the electronic device detecting whether the abnormal state occurs in the signal processor under test according to the embodiment in FIG. 3 of the disclosure.

FIG. 5 is a schematic diagram illustrating the controller of the electronic device performing a dynamic configuration of the signal processor according to an embodiment of the disclosure.

FIG. 6 is an operational flow chart illustrating the controller of the electronic device performing the dynamic configuration of the signal processor according to the embodiment in FIG. 5 of the disclosure.

FIG. 7 is a flow chart of an operating method of the electronic device according to an embodiment of the disclosure.

### DETAILED DESCRIPTION OF DISCLOSURED EMBODIMENTS

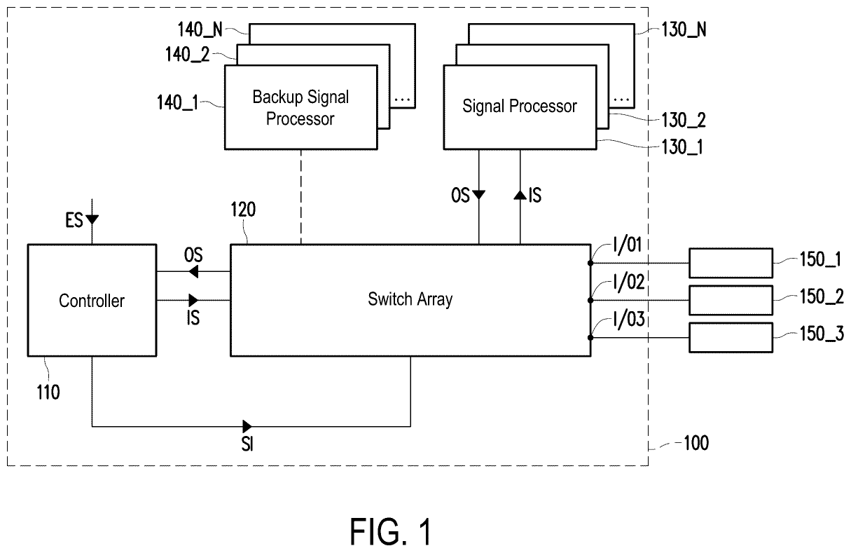

FIG. 1 is a schematic diagram of an electronic device according to an embodiment of the disclosure. Please refer to FIG. 1, an electronic device 100 includes a controller 110, a switch array 120, multiple signal processors 130_1 to 130_N, and multiple backup signal processors 140_1 to 140_N, where N is a positive integer.

In the embodiment, the controller 110 is coupled to the switch array 120. The controller 110 may generate a switching instruction SI to the switch array 120 according to a requirement (or an instruction signal) of the electronic device 100. The controller 110 in the embodiment may be, for example, a microcontroller unit (MCU).

In the embodiment, the switch array 120 may be composed of multiple switch arrays SW1 to SWN. The switch array 120 may receive the switching instruction SI generated by the controller 110. Thereby, the controller 110 may control or switch the switch arrays SW1 to SWN in the switch array 120 according to the switching instruction SI. The switch array 120 in the embodiment has multiple input/output terminals I/O1 to I/O3. The switch array 120 may be coupled to multiple peripheral circuits 150_1 to 150_3 through the input/output terminals I/O1 to I/O3 according to the switching instruction SI.

In an embodiment, the number of the input/output terminals I/O1 to I/O3 and the number of the peripheral circuits 150_1 to 150_3 of the switch array 120 are not limited to 3. The number of input/output terminals and peripheral circuits in the embodiment may be adjusted according to the design requirement of the electronic device 100, which is not particularly limited by the disclosure. Additionally, the peripheral circuits 150_1 to 150_3 in the embodiment may be, for example, a lens module, a motor module, and a sensor respectively, but the disclosure is not limited thereto.

On the other hand, the processors 130_1 to 130_N in the embodiment are coupled to the switch array 120. The signal processors 130_1 to 130_N may be multiple sub-circuit components in the electronic circuit. For example, the signal processors 130_1 to 130_N may be electronic circuits for processing signals, such as amplifiers, filters, analog-to-digital converters, and/or digital-to-analog converters. The backup signal processors 140_1 to 140_N in the embodiment may be electronic circuits with the same functions as the signal processors 130_1 to 130_N.

In other words, in the embodiment, the switch array 120 of the electronic device 100 may be controlled by the controller 110 to adjust or switch the coupling relationship between the controller 110 and the signal processors 130_1 to 130_N, the backup signal processors 140_1 to 140_N, and/or the peripheral circuits 150_1 to 150_3.

In an embodiment, the controller 110 may control the switch array 120 to be coupled to one of the peripheral circuits 150_1 to 150_3 according to the switching instruction SI in different time intervals. In this manner, the controller 110 may be connected to the peripheral circuit through the switch array 120 and configure the signal processors 130_1 to 130_N to the connected peripheral circuit, thereby achieving time-division multiplexing.

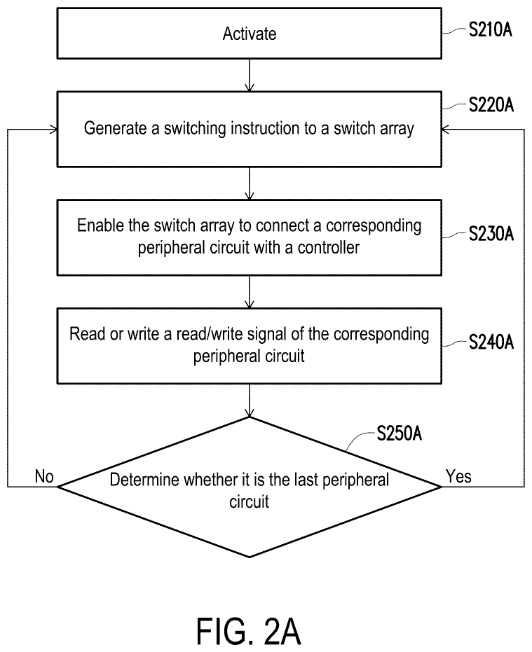

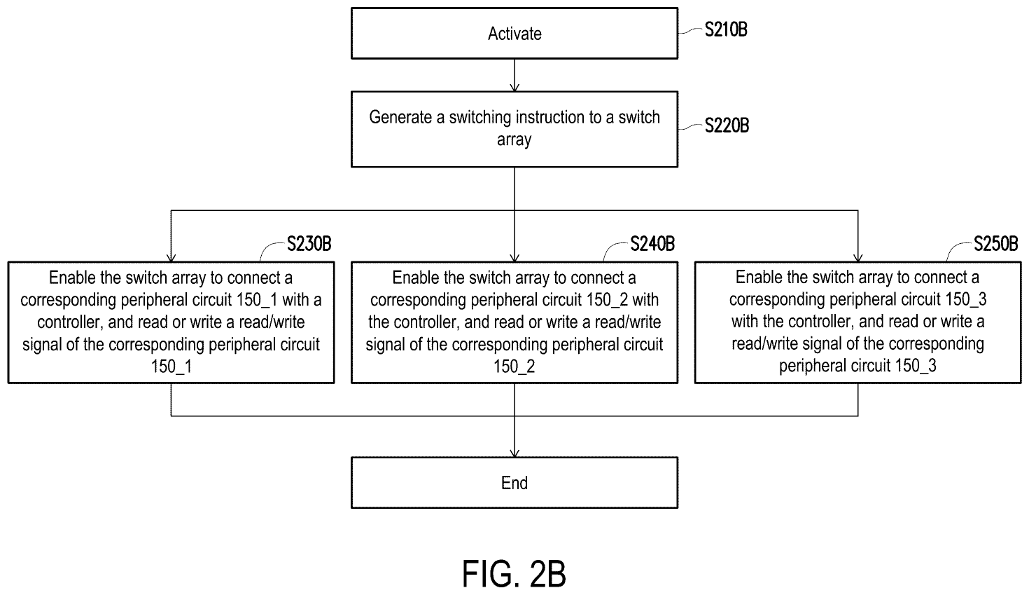

FIG. 2A and FIG. 2B are operational flow charts illustrating a controller of the electronic device controlling a switch array to be sequentially coupled to a peripheral circuit in a time-division manner according to the embodiment in FIG. 1 of the disclosure. Please refer to FIG. 1, FIG. 2A, and FIG. 2B simultaneously. In the embodiment shown in FIG. 2A, the peripheral circuits 150_1 to 150_3 shown in FIG. 1 may respectively have multiple peripheral circuits of the same type. In the embodiment shown in FIG. 2B, the peripheral circuits 150_1 to 150_3 shown in FIG. 1 may respectively have multiple peripheral circuits of different types.

Specifically, in step S210A, the electronic device 100 may activate the controller 110 to enable the controller 110 to perform the operation action of each of the following steps. In step S220A, the controller 110 may generate the corresponding switching instruction SI to the switch array 120 according to the requirement (or the instruction signal) of the electronic device 100.

Then, in step S230A, the controller 110 may control a switching action of the switch array 120 according to the switching instruction SI, and may be connected to the corresponding peripheral circuit (for example, one of the peripheral circuits 150_1 to 150_3) through the switch array 120. In step S240A, the controller 110 may read or write a read/write signal of the corresponding peripheral circuit through a conduction path between the switch array 120 and the corresponding peripheral circuit, thereby confirming that the input/output terminal of the switch array 120 is coupled to corresponding peripheral circuit, and configuring the signal processors 130_1 to 130_N to the corresponding peripheral circuits.

Then, in step S250A, the controller 110 may further determine whether the currently connected peripheral circuit is the last peripheral circuit among all the peripheral circuits 150_1 to 150_3. Furthermore, the controller 110 may perform the operation action of step S220A in a second time interval following a first time interval according to the determination result in step S250A. In other words, the controller 110 in the embodiment may sequentially read or write the read/write signal of each of the peripheral circuit 150_1 to 150_3 in different time intervals, thereby achieving time-division multiplexing.

On the other hand, please refer to FIG. 1 and FIG. 2B simultaneously. In step S210B, the electronic device 100 may activate the controller 110 to enable the controller 110 to perform the operation action of each of the following steps. In step S220B, the controller 110 may generate the corresponding switching instruction SI to the switch array 120 according to the requirement (or the instruction signal) of the electronic device 100.

Then, the controller 110 may control the switching action of the switch array 120 according to the switching instruction SI in different time intervals of steps S230B, S240B, and S250B, and may be connected to the corresponding peripheral circuit through the switch array 120 to read or write the read/write signal of the corresponding peripheral circuit.

For example, in step S230B, the controller 110 may control the switching action of the switch array 120 according to the switching instruction SI, and may be connected to the peripheral circuit 150_1 through the switch array 120 to read or write the read/write signal of the peripheral circuit 150_1. In step S240B, the controller 110 may control the switching action of the switch array 120 according to the switching instruction SI, and may be connected to the peripheral circuit 150_2 through the switch array 120 to read or write the read/write signal of the peripheral circuit 150_2. In step S250B, the controller 110 may control the switching action of the switch array 120 according to the switching instruction SI, and may be connected to the peripheral circuit 150_3 through the switch array 120 to read or write the read/write signal of the peripheral circuit 150_3.

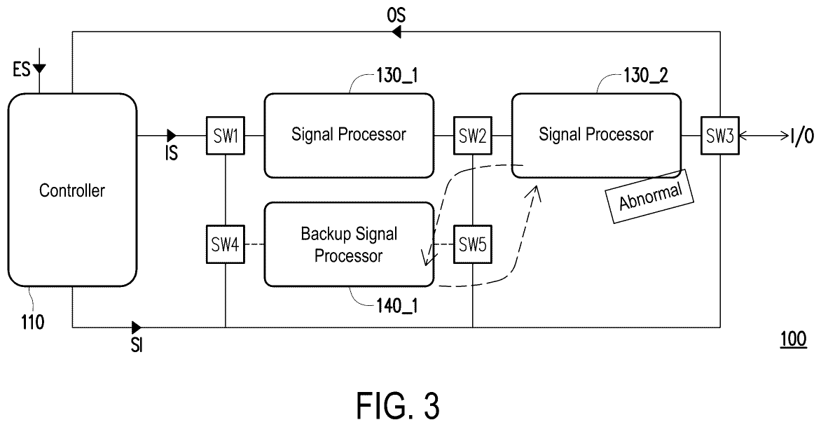

FIG. 3 is a schematic diagram illustrating the controller of the electronic device detecting whether an abnormal state occurs in a signal processor under test according to an embodiment of the disclosure. Please refer to FIG. 1 and FIG. 3 simultaneously. For the convenience of explanation, the electronic device 100 shown in FIG. 3 takes the signal processor 130_1, the signal processor 130_2, and the backup signal processor 140_1 in FIG. 1 as examples for illustration. The action relationship between the remaining signal processor 130_N and the backup signal processor 140_N may be deduced by analogy.

Specifically, in the embodiment, the controller 110 may generate the corresponding switching instructions SI to the switch arrays SW1 to SW5 in the switch array 120 according to the requirement of the electronic device 100, so that the controller 110 may be connected to the signal processors 130_1 and 130_2 through the conduction paths of the switch arrays SW1 to SW3. The controller 110 in the embodiment may detect whether the abnormal state occurs in the signal processor 130_1 or 130_2 through the conduction paths of the switch arrays SW1 to SW3.

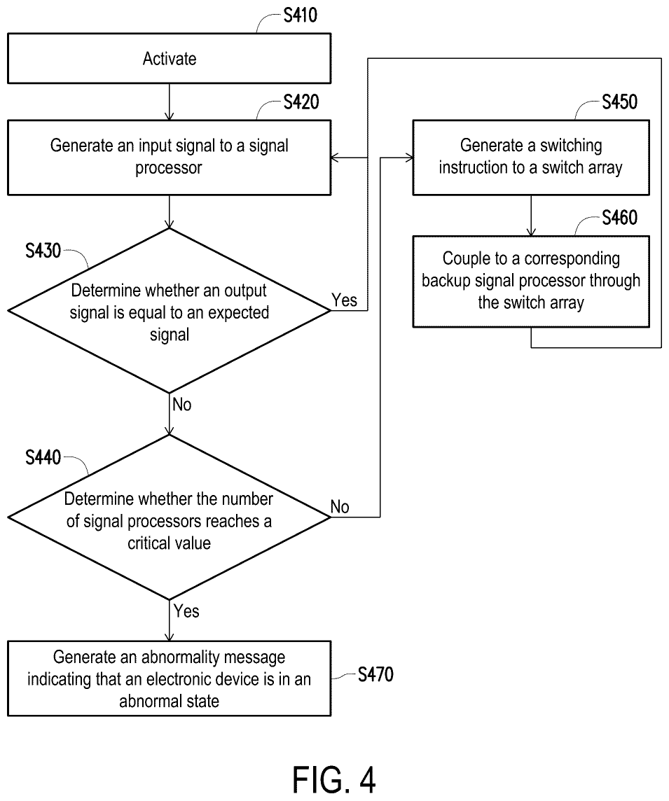

In this regard, the embodiment in FIG. 3 takes the signal processor 130_2 as the signal processor under test as an example for illustration. For the implementation detail of the controller 110 detecting whether the abnormal state occurs in the signal processor 130_2, please refer to FIG. 1, FIG. 3, and FIG. 4 simultaneously. FIG. 4 is an operational flow chart illustrating the controller of the electronic device detecting whether the abnormal state occurs in the signal processor under test according to the embodiment in FIG. 3 of the disclosure. Specifically, in step S410A, the electronic device 100 may activate the controller 110 to enable the controller 110 to perform the operation action of each of the following steps.

Then, in step S420, the controller 110 may transmit an input signal IS to the signal processor under test 130_2 through the conduction paths of the switch arrays SW1 and SW2. Furthermore, the signal processor 130_2 may generate a corresponding output signal OS according to the input signal IS, and transmit the output signal OS to the controller 110 through the conduction path of the switch arrays SW3.

On the other hand, in step S430, after the controller 110 receives the output signal OS, the controller 110 may determine whether the output signal OS is equal to a preset expected signal ES according to the output signal OS and the expected signal ES, and generate a detection result correspondingly.

For example, when the detection result indicates that the output signal OS is equal to the expected signal ES, it means that the signal processor 130_2 under test is in a normal state. In this case, the electronic device 100 may operate normally, and the controller 110 may continue to perform the operation action of step S420. On the contrary, when the detection result indicates that the output signal OS is not equal to the expected signal ES, it means that the signal processor 130_2 under test is in the abnormal state. In this case, the controller 110 may continue to perform the operation action of step S440.

Then, based on the signal processor 130_2 under test being in the abnormal state, in step S440, the controller 110 may further determine whether the number of the backup signal processors 140_1 to 140_N configured in the electronic device 100 reaches a preset critical value. For example, if the current number of the backup signal processors 140_1 to 140_N does not reach the critical value, it means that the electronic device 100 has enough backup signal processors to replace the signal processor 130_2 in the abnormal state. In this case, the controller 110 may continue to perform the operation action of step S450.

On the contrary, if the current number of the backup signal processors 140_1 to 140_N reaches the critical value, it means that the electronic device 100 does not have enough backup signal processors to replace the signal processor 130_2 in the abnormal state. In this case, the controller 110 may continue to perform the operation action of step S470 to generate an abnormality message indicating that the electronic device 100 is in the abnormal state, thereby prompting the operator to eliminate the abnormal state of the electronic device 100.

In another embodiment, the controller 110 may further include reading multiple circuit parameters corresponding to a specific circuit from a database. For example, when the controller 110 determines in step S440 that the number of the backup signal processors 140_1 to 140_N reaches the critical value, the controller 110 may read or search for the circuit parameters corresponding to the signal processor 130_2 under test from the database. Furthermore, the controller 110 may obtain the backup signal processor according to the circuit parameters to construct a digital filter, for example, by executing software. After the controller 110 obtains the backup signal processor, the controller 110 may continue to perform the operation action of step S450.

In the above selection of the circuit parameters, in the embodiment, the method of artificial intelligence may be applied to perform a training action for the circuit parameters of the backup signal processor according to a requirement parameter of the electronic device 100. Through this, trained data may be stored in the above database. In this way, the controller 110 may generate the corresponding backup signal processor based on the database according to the circuit parameters of the signal processor 130_2 under test.

On the other hand, based on the controller 110 determining that the output signal OS is not equal to the expected signal ES (that is, step S430 is “No”) and the number of the backup signal processors 140_1 to 140_N does not reach the critical value (that is, step S440 is “No”), in steps S450 and S460, the controller 110 may generate the switching instruction SI to the switch arrays SW1 to SW5 according to the determination results of steps S430 and S440, thereby changing the conduction states of the switch arrays SW1 to SW5.

For example, the switch array SW2 of the switch array 120 may disconnect the connection between the controller 110 and the signal processor 130_2 in the abnormal state according to the switching instruction SI. Furthermore, the switch arrays SW4 and SW5 of the switch array 120 may change the controller 110 to be coupled to the backup signal processor 140_1 according to the switching instruction SI.

In this way, when the abnormal state occurs in the signal processor 130_2 under test, the controller 110 in the embodiment may replace or substitute the failed signal processor 130_2 with the backup signal processor 140_1 by switching the switch arrays SW1 to SW5, thereby improving the reliability of the electronic device 100.

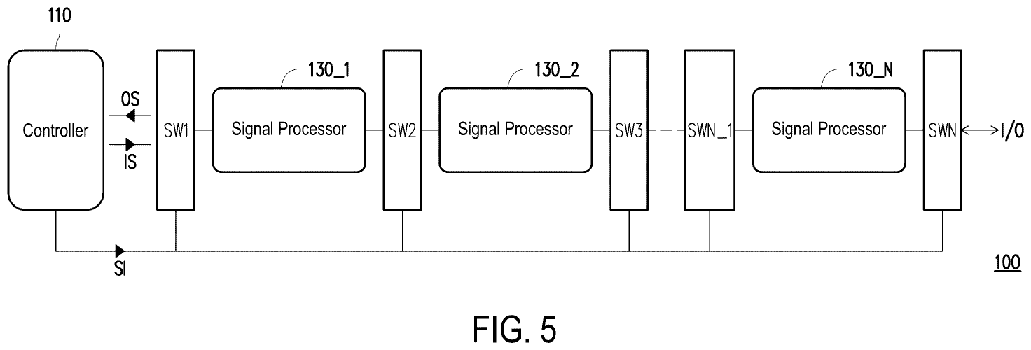

FIG. 5 is a schematic diagram illustrating the controller of the electronic device performing a dynamic configuration of the signal processor according to an embodiment of the disclosure. The embodiment in FIG. 5 takes the signal processor 130_1 as the signal processor under test for illustration.

Specifically, please refer to FIG. 1 and FIG. 5 simultaneously. In the embodiment, the controller 110 may generate the input signal IS to the signal processor 130_1 under test, and the signal processor 130_1 may transmit the corresponding output signal OS to the controller 110 through the switch array SW1 of the switch array 120 according to the input signal IS. Thereby, the controller 110 may determine whether the signal strength of the output signal OS generated by the signal processor 130_1 meets the circuit requirement according to the output signal OS and an expected result. Furthermore, the controller 110 may perform the dynamic configurations of the signal processors 130_1 to 130_N shown in FIG. 1 according to the determination result.

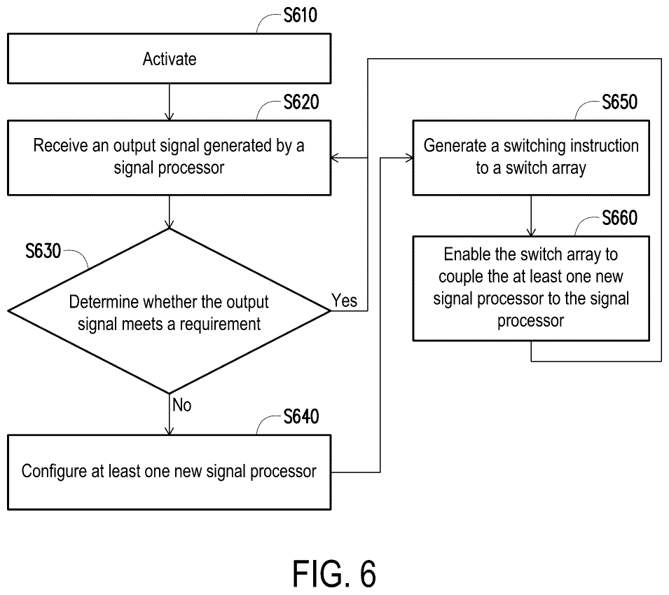

For the implementation detail of the controller 110 performing the dynamic configurations of the signal processors 130_1 to 130_N, please refer to FIG. 1, FIG. 5, and FIG. 6 simultaneously. FIG. 6 is an operational flow chart illustrating the controller of the electronic device performing the dynamic configuration of the signal processor according to the embodiment in FIG. 5 of the disclosure.

Specifically, in step S610, the electronic device 100 may activate the controller 110 to enable the controller 110 to perform the operation action of each of the following steps. Then, in step S620, the controller 110 may generate the input signal IS to the signal processor 130_1 under test. The signal processor 130_1 may transmit the corresponding output signal OS to the controller 110 through the switch array SW1 of the switch array 120 according to the input signal IS.

On the other hand, in step S630 the controller 110 may determine whether the signal strength of the output signal OS generated by the signal processor 130_1 meets the circuit requirement according to the output signal OS and a preset expected result. For example, when the controller 110 generates the input signal IS to the signal processor 130_1 under test, the controller 110 may pre-calculate the signal strength of the output signal OS that meets the circuit requirement to obtain the expected result. The signal strength may be, for example, the noise level of the signal or the gain amount of the signal, which is not particularly limited by the disclosure.

In this regard, for the convenience of explanation, the controller 110 in the embodiment may, for example, perform the dynamic configurations of the signal processors 130_1 to 130_N according to the noise level of the output signal OS of the signal processor 130_1, thereby improving or adjusting the signal strength of the output signal OS.

Furthermore, in step S630, when the controller 110 determines that the signal strength of the output signal OS is the same as the expected result, it means that the noise level of the output signal OS meets the circuit requirement. In this case, the controller 110 may continue to perform the operation action of step S620 according to the determination result.

On the contrary, when the controller 110 determines that the signal strength of the output signal OS is different from the expected result, it means that the noise level of the output signal OS does not meet the circuit requirement, and the output signal OS currently may have excessive noise. In this case, the controller 110 may continue to perform the operation action of step S640 according to the determination result of step S630.

Then, based on the signal strength of the output signal OS not meeting the circuit requirement, in steps S640 to S660, the controller 110 may configure at least one new signal processor (for example, at least one of the signal processors 130_2 to 130_N) according to the determination result to be connected to the signal processor 130_1 under test. The new signal processor may be, for example, a filter circuit.

Furthermore, in step S640 to S660, the controller 110 may generate the switching instruction SI to the switch arrays SW1 to SWN of the switch array 120 according to the determination result of step S630. In this case, the switch arrays SW2 to SWN may enable at least one of the signal processors 130_2 to 130_N to be connected to the signal processor 130_1 under test according to the switching instruction SI. Thereby, the controller 110 in the embodiment may further reduce the noise level of the output signal OS of the signal processor 130_1 by additionally configuring the new signal processor (for example, at least one of the signal processors 130_2 to 130_N).

In other words, in the embodiment, the controller 110 may determine the number of the signal processors 130_2 to 130_N that need to be reconfigured according to the signal strength of the output signal OS and the expected result, thereby reconfiguring the circuit configuration and improving or optimizing the noise level of the output signal OS.

According to the description of the embodiment in FIG. 1 to FIG. 6, it is known that the controller 110 in the embodiment may be sequentially coupled to each of the peripheral circuits 150_1 to 150_3 through switching the switch array 120 in different time intervals to achieve time-division multiplexing. Moreover, when the abnormal state occurs in the signal processor under test, the controller 110 may replace or substitute the failed signal processor with the backup signal processor by switching the switch arrays SW1 to SW5, thereby monitoring the signal quality of each signal processor.

In addition, the controller 110 in the embodiment may also detect the signal strength of the output signal OS of the signal processor under test. Moreover, when the signal strength of the output signal OS does not meet the circuit requirement, the controller 110 may reconfigure the coupling relationship between at least one of the remaining signal processors and the signal processor under test by switching the switch array 120, thereby improving the signal strength of the output signal OS of the signal processor under test and increasing the reliability of the circuit.

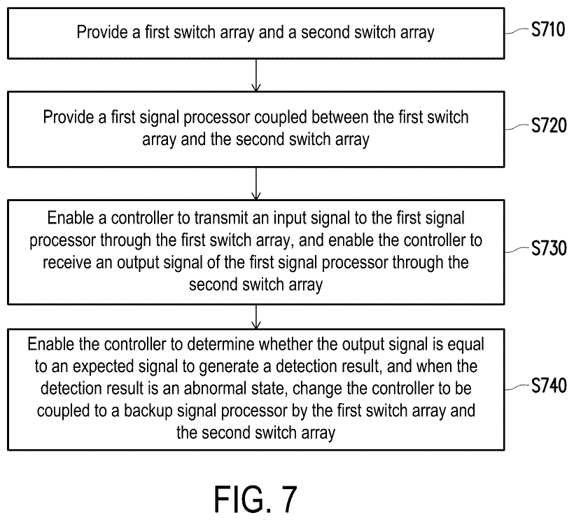

FIG. 7 is a flow chart of an operating method of the electronic device according to an embodiment of the disclosure. Please refer to FIG. 1 and FIG. 7 simultaneously. In step S710, the electronic device may provide a first switch array and a second switch array. In step S720. the electronic device may provide a first signal processor coupled between the first switch array and the second switch array.

On the other hand, in step S730, the electronic device may enable the controller to transmit an input signal to the first signal processor through the first switch array, and enable the controller to receive an output signal of the first signal processor through the second switch array. In step S740, the electronic device may enable the controller to determine whether the output signal is equal to an expected signal to generate a detection result, and when the detection result is an abnormal state, the first switch array and the second switch array change the controller to be coupled to a backup signal processor.

Regarding the implementation detail of each step, the detailed descriptions have been made in the foregoing embodiments and implementation methods and will not be described in detail here.

In summary, in the electronic device and the operating method thereof according to the embodiments of the discourse, when the abnormal state occurs in the signal processor under test, the controller may replace or substitute the failed signal processor with the backup signal processor by switching the switch array, thereby monitoring the signal quality of each signal processor. In addition, the controller may detect the signal strength of the output signal of the signal processor under test, and when the signal strength of the output signal does not meet the circuit requirement, the controller may reconfigure the coupling relationship between at least one of the remaining signal processors and the signal processor under test by switching the switch array, thereby improving the signal strength of the output signal and increasing the reliability of the circuit.

What is claimed is:

1. An electronic device, comprising:
a first switch array and a second switch array;
a first signal processor, coupled between the first switch array and the second switch array; and
a controller, coupled to the first switch array and the second switch array, wherein the controller transmits an input signal to the first signal processor through the first switch array, and receives an output signal of the first signal processor through the second switch array, and the controller determines whether the output signal is equal to an expected signal to generate a detection result,
wherein when the detection result is an abnormal state, the first switch array and the second switch array change the controller to be coupled to a backup signal processor.

2. The electronic device according to claim 1, wherein the controller is further coupled to a plurality of peripheral circuits through the first switch array, and enables the first switch array to be sequentially coupled to each of the peripheral circuits in a time-division manner.

3. The electronic device according to claim 1, wherein the electronic device further comprises N third switch arrays and N second signal processors, wherein the controller determines whether a signal of the output signal is the same as an expected result, and when the controller determines that the signal of the output signal is different from the expected result, the controller controls the N third switch arrays to be coupled to the N second signal processors respectively according to a switching instruction, and enables a second signal processor among the N second signal processors to be coupled between the second switch array and a third switch array among the N third switch arrays.

4. The electronic device according to claim 3, wherein the first signal processor and the N second signal processors are a plurality of sub-circuit components in an electronic circuit.

5. The electronic device according to claim 1, wherein the first signal processor and the backup signal processor have a same function.

6. The electronic device according to claim 1, wherein the controller further comprises reading a plurality of circuit parameters corresponding to a specific circuit from a database, and forming the backup signal processor according to the circuit parameters.

7. An operating method of an electronic device, comprising:
providing a first switch array and a second switch array;
providing a first signal processor coupled between the first switch array and the second switch array;
enabling a controller to transmit an input signal to the first signal processor through the first switch array, and enabling the controller to receive an output signal of the first signal processor through the second switch array; and
enabling the controller to determine whether the output signal is equal to an expected signal to generate a detection result, and when the detection result is an abnormal state, changing the controller to be coupled to a backup signal processor by the first switch array and the second switch array.

8. The operating method according to claim 7, further comprising:
enabling the controller to be coupled to a plurality of peripheral circuits through the first switch array, and enabling the first switch array to be sequentially coupled to each of the peripheral circuits in a time-division manner.

9. The operating method according to claim 7, further comprising:
providing N third switch arrays and N second signal processors;
enabling the controller to determine whether a signal of the output signal is the same as an expected result, and when the controller determines that the signal of the output signal is different from the expected result, enabling the controller to control the N third switch arrays to be coupled to the N second signal processors respectively according to a switching instruction, and enabling a second signal processor among the N second signal processors to be coupled between the second switch array and a third switch array among the N third switch arrays.

10. The operating method according to claim 9, wherein the first signal processor and the N second signal processors are a plurality of sub-circuit components in an electronic circuit.

11. The operating method according to claim 7, wherein the first signal processor and the backup signal processor have a same function.

12. The operating method according to claim 7, further comprising:
providing a plurality of circuit parameters corresponding to a specific circuit read from a database, and enabling the controller to form the backup signal processor according to the circuit parameters.
